(19) United States
(12) Patent Application Publication
(10) Pub. No.: US 2008/0305638 A1
(43) Pub. Date: Dec. 11, 2008

(54) Coating compositions for use in forming patterns and methods of forming patterns

(76) Inventors: Sang-jung Choi, Seoul (KR); Mitsuhiro Hata, Suwon-si (KR); Man-hyoung Ryoo, Hwaseong-si (KR); Jung-hwan Hah, Hwaseong-si (KR)

Correspondence Address: HARNESS, DICKEY & PIERCE, P.L.C., P.O. BOX 8910, RESTON, VA, 20195, US

(21) Appl. No.: 12/222,433

(22) Filed: Aug. 8, 2008

Related U.S. Application Data
(62) Division of application No. 11/397,882, filed on Apr. 5, 2006.

(30) Foreign Application Priority Data
Aug. 31, 2005 (KR) 10-2005-0080616

(51) Int. Cl. H01L 21/311

(52) U.S. Cl. 438/700; 257/E21.249

(57) ABSTRACT

A coating composition for forming etch mask patterns may include a polymer and an organic solvent. The polymer may have an aromatic ring substituted by a vinyl ether functional group. The polymer may be, for example, a Novolak resin partially substituted by a vinyl ether functional group or poly(hydroxystyrene) partially substituted by a vinyl ether functional group.

### PRIORITY STATEMENT

This application claims priority under 35 U.S.C. § 119 to Korean Patent Application No. 10-2005-0080616, filed on Aug. 31, 2005, in the Korean Intellectual Property Office (KIPO), the entire contents of which are incorporated herein by reference.

### BACKGROUND OF THE INVENTION

1. Field of the Invention

Example embodiments of the present invention relate to coating compositions for forming etch mask patterns used in manufacturing semiconductor devices, and methods of forming fine patterns in semiconductor devices using the coating composition.

2. Description of the Related Art

In related art methods of forming patterns, a photoresist pattern may be formed on an etch target layer (e.g., a silicon layer, an insulation layer or a conductive layer). The etch target layer may be etched using the photoresist pattern as an etch mask.

As semiconductor devices become increasingly integrated, smaller critical dimensions (CD) may be needed, and thus, methods of forming a fine pattern having smaller openings, contact holes and/or smaller widths may be required. Related art lithography processes using an ArF excimer laser having a wavelength of 193 nm and immersion lithography technology have been used in attempts to reduce the size of openings, contact holes and/or widths within the related art patterns.

However, due to material and/or process limitations, developing semiconductor devices using next generation materials has become increasingly difficult. For example, in the ArF laser lithography process, components, layers, etc., may be susceptible to dry etching and/or line edge roughness (LEG).

In addition, forming a fine contact hole may be increasingly difficult using related art photolithography processes. For example, a contact hole having a size smaller than 100 nm may be more difficult to achieve because a contact hole pattern has lower resist resolution than a line and space pattern.

Various techniques have been used in attempt to produce smaller feature size, for example, a thermal flow process (TFP). In the TFP, a resist pattern may be heat treated to change the cross-sectional shape and/or size of the resist pattern. In doing so, the resist flow in an upper portion of the resist pattern may not be equal to the resist flow in a middle portion of the resist pattern. When the CD decreases due to the thermal flow of the resist pattern greater than 100 nm, the profile of the photoresist pattern may be deformed due to the flow characteristics of the resist layer. As a result, a bowing profile and/or swelling may occur.

Accordingly, because the flow rate of the photoresist pattern may be more difficult to control when the above-described example method is used, it may be more difficult to decrease the CD while maintaining the vertical pattern profile. In addition, differences in the CD may be generated on a substrate due to a bulk effect caused by density differences in a pattern formed on a substrate. Although the differences in the CD may be reduced for a contact hole pattern having a uniform size and/or duty, it may be more difficult to reduce the deformation of the pattern shape at pattern edges and applications of the TFP may be limited.

Another example related art method for reducing feature size is referred to as a chemical shrink process (CSP). In the CSP, after forming a resist pattern, an intermixing layer using a mutual interaction of the resist pattern may be formed using a water-soluble polymer material. As a result, the CD may be reduced in its entirety.

A related art technique related to the CSP, resolution enhancement lithography assisted by chemical shrink (RELACS) may be used to form a fine contact hole. In the RELACS, a water-soluble polymer and crosslinker may be used as overcoating materials in a photolithography process using, for example, an i-line or a KrF resist material. In this example, a first resist pattern may be formed using the KrF resist, and coated with a second resist solution formed of a water-soluble polymer and a hardener. During a baking process, the acid on the surface of the first resist pattern may be diffused to the second resist solution, and as a result a crosslink reaction may occur. A crosslinked layer and an uncrosslinked layer disposed in the interface of the first resist pattern and the second resist solution may be developed using a developing solution including deionized water such that the uncrosslinked layer may be removed and a contact hole pattern having a smaller size than the original contact hole disposed in the first resist pattern may be formed.

In RELACS, however, because the solubility of the water-soluble polymer and the crosslinker to the deionized water is limited, an organic solvent such as IPA is utilized. When developed using only the deionized water, defects may be generated on a substrate. To suppress these defects, an IPA treatment process may be performed first and the treatment using the deionized water may be performed during the final developing process. As a result, the process may become more complicated and/or expensive. Although the RELACS may be used in an ArF lithography process, defects remain after the process and/or susceptibility to dry etching remains.

Reducing CD according to the related art techniques may be more difficult when a light source having a wavelength of 153 nm or 196 nm as an exposure light source is used, and/or when the size of a hole or a trench to be obtained decreases.

### SUMMARY OF THE INVENTION

Example embodiments of the present invention provide coating compositions for forming etch mask patterns, usable in forming fine patterns. Coating compositions according to example embodiments of the present invention may overcome a wavelength limitation in a lithography process by forming an overcoating layer having an improved durability against dry etching.

Example embodiments of the present invention also provide methods of forming fine patterns having a smaller feature size, which may improve the durability against dry etching, line edge roughness (LER) characteristics, reduce the deformation of the sidewall profiles of apertures, and/or create a fine pattern having a smaller feature size.

The coating composition according to example embodiments of the present invention may be used in a lithography process forming a fine patter used in semiconductor devices such that improved durability against dry etching may be obtained and/or LER may be reduced. In addition, a fine pattern having a smaller feature size may be effectively achieved by reducing the deformation of the side wall profiles of apertures.

According to an example embodiment of the present invention, a coating composition may include a polymer and an organic solvent. The polymer may have an aromatic ring substituted by a vinyl ether functional group.

In example embodiments of the present invention, the polymer may be a Novolak resin partially substituted by a vinyl ether functional group or poly(hydroxystyrene) partially substituted by a vinyl ether functional group. The coating composition may further include about 0.1 wt % to about 10 wt %, inclusive, of an acid based on the total weight of the coating composition.

Another example embodiment of the present invention provides a method of forming a fine pattern. According to at least one example embodiment of the present invention, an underlayer may be formed on a semiconductor substrate. A resist pattern having an aperture exposing the underlayer may be formed on the underlayer. A coating composition may be deposited on the surface of the resist pattern. The coating composition may include a polymer and an organic solvent. The polymer may have an aromatic ring substituted by a vinyl ether functional group. The polymer may be crosslinked to form an overcoating layer on a surface of the resist pattern. The underlayer may be etched using the resist pattern and the overcoating layer as an etch mask.

In example embodiments of the present invention, the crosslinking may be induced using an acid catalyst. The acid may be, for example, the acid in the resist pattern, such as, one of trifluoroacetic acid, trifluoromethanesulfonic acid or a combination thereof. The crosslinking may be performed at a temperature between about 90° C. to about 120° C., inclusive. In at least some example embodiments of the present invention, residual coating composition around the overcoating layer may be removed using an alkaline developing solution after the forming of the overcoating layer.

In example embodiments of the present invention, the concentration of the polymer may be about 10 ppm to about 10 wt %, inclusive, based on the total weight of the organic solvent. The organic solvent may be alcohol. The resist pattern may be a chemically amplified resist composition, and may be a resist composition for a KrF excimer laser having a wavelength of about 248 nm, a resist composition for an ArF excimer laser having a wavelength of about 193 nm or a resist composition an F2 excimer laser having a wavelength of about 157 nm. The coating composition may be deposited on the surface of the resist using spin coating, puddling, dipping or spraying. The developing solution may be about 2.38 wt % of a tetramethylammonium hydroxide (TMAH) solution.

### BRIEF DESCRIPTION OF THE DRAWINGS

The present invention will become more apparent by describing in detail example embodiments shown in the drawings in which:

FIGS. 1A through 1F are cross-sectional views illustrating a method of forming a pattern for use in a semiconductor device, according to an example embodiment of the present invention.

### DETAILED DESCRIPTION OF EXAMPLE EMBODIMENTS OF THE PRESENT INVENTION

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Resolution enhancement lithography assisted by chemical shrink (RELACS), may be used to obtain a pattern having a reduced size using a material including different polymers and/or different reaction mechanism materials from the conventional art. In at least some example embodiments of the present invention, a coating composition having overcoating polymers may be formed of an aromatic compound instead of water-soluble polymer. The coating composition, according to example embodiments of the present invention, may be dissolved in a resist developing solution such as an alkaline solution (e.g., a 2.38 wt % tetramethylammonium hydroxide (TMAH) solution), and may form an intermixing layer as a result of a (e.g., only a) reaction with a lower resist pattern without a crosslinker. For example, in the coating composition according to example embodiments of the present invention, the aromatic polymer compound used for reducing a pattern may include a vinyl ether functional group and may be dissolved in a resist developing solution. The ether functional group included in the aromatic polymer may be formed in an intermixing layer undissolved in the developing solution by, for example, crosslinking carboxylic acid, a hydroxyl group or the like in the lower resist pattern with an acid catalyst, thereby forming an overcoating layer on a surface of the initial resist pattern. Accordingly, a mask pattern providing a smaller-sized CD than that produced by the initial resist pattern may be obtained.

In the coating composition, according to example embodiments of the present invention, the aromatic polymer may include, for example, a hydroxyl group, an acid group or the like in its polymer chain and may be more easily dissolved in a resist developing solution, for example, a Novolak resin, poly(hydroxystyrene) or the like. The aromatic polymer may be dissolved in an organic solvent. About 10 ppm to about 10 wt %, inclusive, of the polymer based on the total weight of the organic solvent may be included.

In the coating composition according to example embodiments of the present invention, the acid in the resist pattern may be used as an acid catalyst for the crosslinking of the vinyl ether functional group included in the aromatic polymer and the carboxylic acid or the hydroxyl group in the lower resist pattern. When the resist pattern is formed, the acid generated from the resist layer during the exposure may be diffused in a post-exposure baking process. When a positive resist layer is formed, deprotection may occur in which a protection group may be separated from the polymer at an exposed portion of the resist layer due to the diffused acid, thereby selectively developing the exposed portion of the resist layer. When a negative resist layer is formed, the polymer may be crosslinked at the exposed portion of the resist layer due to the diffused acid, thereby selectively developing the unexposed portion of the resist layer. In each example case, a smaller amount of the acid remains between the exposed portion and the unexposed portion of the resist layer. The residual acid remaining in the resist pattern may function as a catalyst when the vinyl ether functioning group included in the polymer of the coating composition according to example embodiments of the present invention crosslinks carboxylic acid and a hydroxyl group in the lower resist pattern.

Alternatively, trifluoroacetic acid, trifluoromethanesulfonic acid, a combination thereof or the like may be included as an acid catalyst in the coating composition. The amount of the acid included in the coating composition may be about 0.1 wt % to about 10 wt %, inclusive, based on the total weight of the coating composition.

The polymer included in the coating composition according to example embodiments of the present invention may have an aromatic ring substituted by a vinyl ether functional group. Accordingly, the strength problem of related art ArF resist materials may be improved. For example, the Novolak resin may have a lower glass transition temperature (Tg). Accordingly, a heat treatment process may be performed in order to suppress and/or prevent a line edge roughness (LER) problem, which may occur when an overcoating layer on a resist pattern using a developing solution. By performing the heat treatment process, the surface of the overcoating layer may be planarized without a thermal influence on the lower resist pattern, thereby producing a mask pattern having a cleaner surface.

In addition, defects may be generated during the formation of an overcoating layer due to, for example, solubility of water-soluble polymers and reaction with a crosslinker. However, polymers in the coating composition according to example embodiments of the present invention may be removed using a resist developing solution. Accordingly, the defects generated by the solubility difference in the polymers may be reduced.

In example embodiments of the present invention, aromatic overcoating materials dissolved in a developing solution may be used to form an overcoating layer on a surface of a resist pattern, thereby forming a fine pattern which may increase the limit of the wavelength of an exposure light source in the manufacture of semiconductor devices.

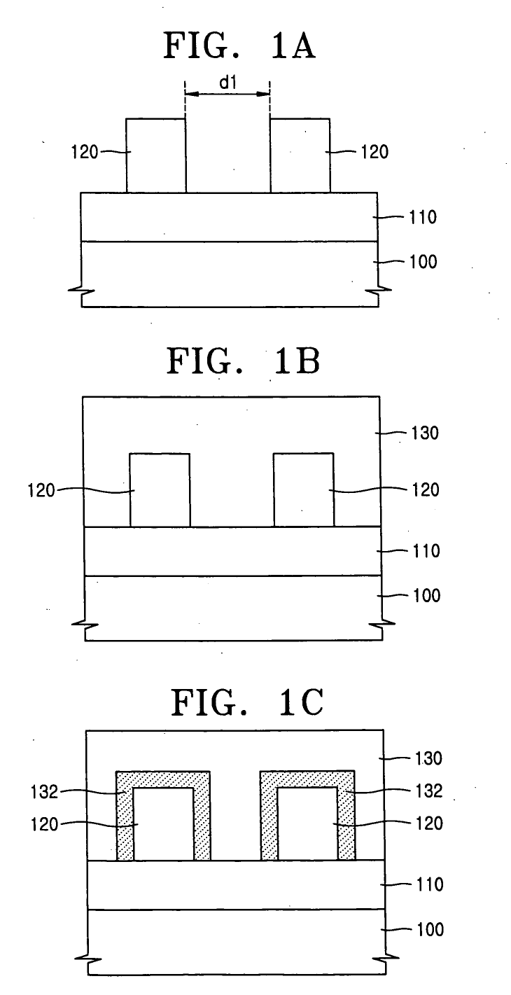

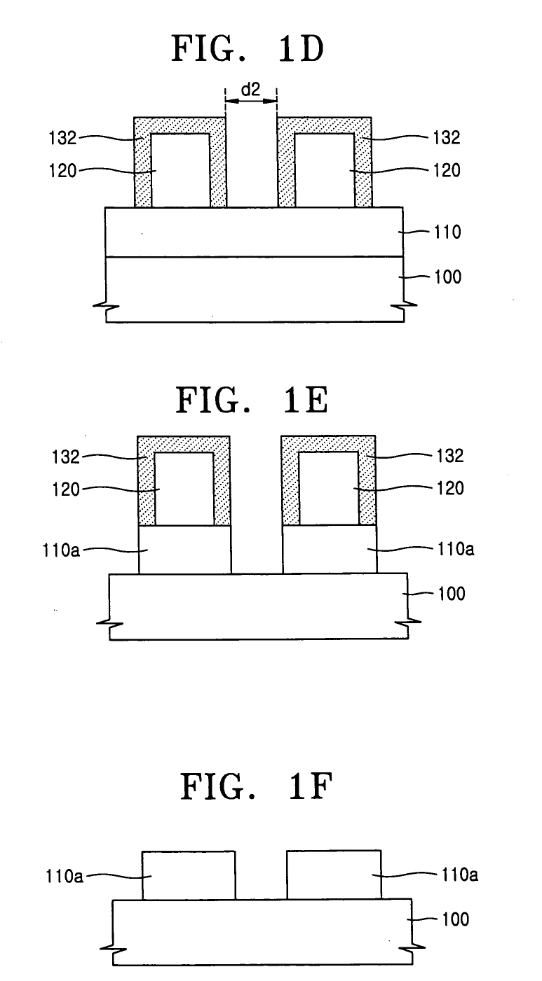

FIGS. 1A through 1F are cross-sectional views illustrating a method of manufacturing a semiconductor device, according to an example embodiment of the present invention.

Referring to FIG. 1A, a given or desired pattern, for example, an underlayer 110, such as an etch target layer for forming a contact hole or a trench, may be formed on a semiconductor substrate 100. The underlayer 110 may be, for example, an insulation layer, a conductive layer, a semiconductor layer or the like.

A resist pattern 120 may be formed on the underlayer 110. A first aperture having a first diameter d1, exposing the upper surface of the underlayer 110 may be formed in the resist pattern 120. The resist pattern 120 may include a plurality of these first apertures defining a hole pattern, or may be a pattern having a plurality of lines defining a line and space pattern. When the resist pattern 120 may be a pattern having a plurality of lines, the first width d1 corresponds to a width between the lines.

The resist pattern 120 may be formed of a chemically amplified resist composition including a photo acid generator (PAG). For example, the resist pattern 120 may be formed of a resist composition for a g-line, a resist composition for an i-line, a resist composition for a KrF excimer laser having a wavelength of about 248 nm, a resist composition for an ArF excimer laser having a wavelength of about. 193 nm, a resist composition for an F₂ excimer laser having a wavelength of about 157 nm, a resist composition for an e-beam or the like. The resist pattern 120 may be formed of a positive resist composition or a negative resist composition.

Referring to FIG. 1B, a coating composition 130 comprised of the coating composition according to an example embodiment of the present invention, and which has a polymer for overcoating including an aromatic ring substituted by a vinyl ether functional group, may be contacted to a surface of the resist pattern 120. When the semiconductor substrate 100 is rotated at a speed of about 500 rpm to about 3000 rpm, inclusive, for about 30 to about 90 seconds, inclusive, the coating composition 130 may be applied to the resist pattern 120.

Referring to FIG. 1C, when the coating composition 130 contacts the surface of the resist pattern 120, the semiconductor substrate 100 may be heated, and the polymer for overcoating may be crosslinked on the surface of the resist pattern 120, thereby forming an overcoating layer 132 on the surface of the resist pattern 120. The heating may be performed at a temperature between about 90° C. and 120° C., inclusive. The overcoating layer 132 formed in the above-described manner may be insoluble with respect to the developing solution. The resist pattern 120 and the overcoating layer 132 may be mask patterns used as an etch mask when the underlayer 110 is etched.

Referring to FIG. 1D, a residual coating composition around the overcoating layer 132 may be removed using an alkaline developing solution, for example, a 2.38 wt % tetramethylammonium hydroxide (TMAH) solution. After removing the residual coating composition using the developing solution, a rinse process using deionized water may be performed.

The underlayer 110 may be exposed by a second aperture having a second diameter d2, which may be smaller than the first diameter d1 of the first aperture of the resist pattern 120 on the semiconductor substrate 100. The exposed portion of the underlayer 110 may be defined by the overcoating layer 132 formed on the surface of the resist pattern 120.

Referring to FIG. 1E, the underlayer 110 may be dry etched using the resist pattern 120 and the overcoating layer 132 as an etch mask to form an underlayer pattern 110a.

Referring to FIG. 1F, the mask pattern formed of the resist pattern 120 and the overcoating layer 132 may be removed.

Experimental examples for synthesizing polymers used in the manufacture of a coating composition according to example embodiments of the present invention and for forming a fine pattern of a semiconductor device using the coating composition will be described.

These examples are for example purposes only, however, to fully convey the concept of the present invention to those skilled in the art, but not to limit the present invention.

### Example 1

### Synthesis of a Polymer for a Coating Composition (I)

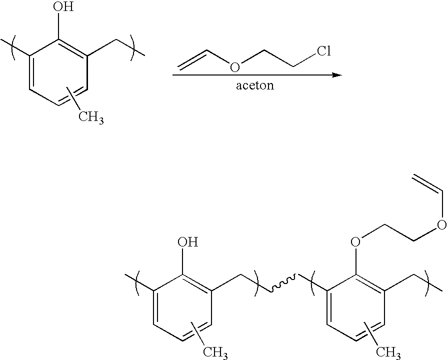

In Example 1, 6 g (50 mmol) of Novolak resin (Mw=9,200) and 7 g (50 mmol) of potassium carbonate were dissolved in 50 ml of acetone in a round bottom flask, and 2.7 g (25 mmol) of 2-chloroethyl vinyl ether was slowly dropped in the solution. The mixture was reacted for about 12 hours.

After the reaction, the obtained precipitations were removed, the reacted materials were slowly precipitated in water, and then the obtained precipitations were filtrated. The filtrated precipitations were dissolved again in a proper amount of THF solution and were slowly precipitated again in an n-hexane solution. The obtained precipitations were dried at about 50° C. for about 24 hours in a vacuum oven. The yield was 85%.

The result had a weight average molecular weight (Mw) of 11,500 daltons and a polydispersity (Mw/Mn) of 2.6.

### Example 2

### Synthesis of a Polymer for a Coating Composition (II)

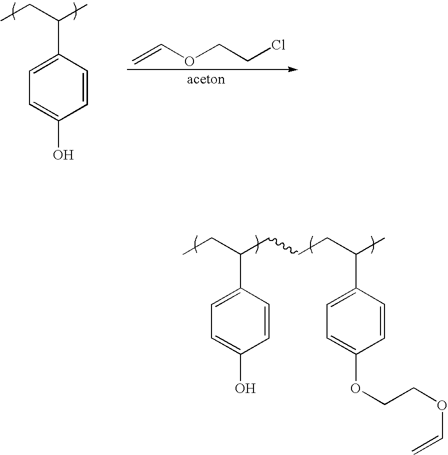

In Example 2, 6 g (50 mmol) of poly 4-hydroxy styrene (Mw=10,000) and 7 g (50 mmol) of potassium carbonate were dissolved in 50 ml of acetone in a round bottom flask, and 2.7 g (25 mmol) of 2-chloroethyl vinyl ether was slowly dropped in the solution. The mixture was reacted for about 12 hours.

After the reaction, the obtained precipitations were removed, the reacted materials were slowly precipitated in water, and then the obtained precipitations were filtrated. The filtrated precipitations were dissolved again in a proper amount of THF solution and were slowly precipitated again in an n-hexane solution. The obtained precipitations were dried at about 50° C. for about 24 hours in a vacuum oven. The yield was 87%.

The result had a weight average molecular weight (Mw) of 12,500 daltons and a polydispersity (Mw/Mn) of 1.6.

### Example 3

### Evaluation of Lithography (I)

In Example 3, 1 g of the polymer of Example 1 was dissolved in 40 g of n-butanol and filtrated though a membrane filter of 0.2 μm, to obtain a coating composition for overcoating.

Anti-reflective coating (ARC) material (such as an ArF Anti-reflective coating) for an exposure wavelength of 193 nm was spin-coated on an 8-inch bare silicon wafer, and baked to form an ARC layer having a thickness of about 240 Å.

A photoresist used for an exposure wavelength of 193 nm was spin-coated on the ARC layer, and pre-baked at 110° C. for 60 seconds, to form a photoresist layer.

The surface of the wafer was exposed to an ArF excimer laser using an ArF scanner with NA=0.75 annular and σ=0.85/0.55, subjected to post-exposure bake (PEB) at 110° C. for 60 seconds, and developed with a 2.38% tetramethylammonium hydroxide solution for 60 seconds. When a dose was 30 mJ/cm², a resist pattern having a contact hole pattern with a hole diameter of about 130 nm was obtained.

The coating composition was coated to a thickness of about 800 Å on the resist pattern having the contact hole pattern. The coated product was baked at about 120° C. for 60 seconds to induce a crosslink reaction of the overcoated polymers. The unreacted coating composition was removed using 2.38 wt % TMAH solution for 60 seconds. The product was rinsed using deionized water.

From the results of investigating the final product using SEM, a clean contact hole pattern having apertures of about 110 nm in diameter, which is 20 nm less, was obtained.

### Example 4

### Evaluation of Lithography (II)

In Example 4, 1 g of the polymer of Example 1 was dissolved in 40 g of n-butanol with 0.02 g (2 wt %) of trifluoroacetic acid (TFA) and filtrated though a membrane filter of 0.2 μm, thereby obtaining a coating composition for overcoating.

A resist pattern having a contact hole pattern with a hole diameter of about 130 nm was formed on a wafer using the same method described in Example 3.

The coating composition was coated to a thickness of about 800 Å on the resist pattern of the wafer. An overcoating layer was formed on the resist pattern using the method described in Example 3.

From the results of investigating the final product using SEM, a clean contact hole pattern having apertures of about 100 nm in diameter, which is 30 nm less, was obtained.

### Example 5

### Evaluation of Lithography (III)

In Example 5, 1 g of the polymer of Example 2 was dissolved in 40 g of n-butanol and filtrated though a membrane filter of 0.2 μm, thereby obtaining a coating composition for overcoating.

A resist pattern having a contact hole pattern with a hole diameter of about 130 nm was formed on a wafer using the method described in Example 3.

The coating composition was coated to a thickness of about 800 Å on the resist pattern of the wafer. An overcoating layer was formed on the resist pattern using the method described in Example 3.

From the results of investigating the final product using SEM, a clean contact hole pattern having apertures of about 100 nm in diameter, which is 30 nm less, was obtained.

In example embodiments of the present invention, an overcoating layer may be formed on a resist pattern in order to form a mask pattern having fine-sized apertures that increase and/or overcome wavelength limitations in related art photolithography technology. In the present invention, a coating composition including polymers having an aromatic ring substituted by a vinyl ether functional group may be used to form the overcoating layer. As the polymer compound including polymers having an aromatic ring substituted by a vinyl ether functional group, a Novolak resin may be more easily dissolved in an alkaline developing solution or a poly(hydroxystyrene) resin. In addition, an overcoating layer undissolved in a developing solution may be formed on a resist pattern by a crosslinking reaction with the lower resist pattern without a crosslinker. The coating composition according to example embodiments of the present invention may be employed in a lithography process for forming a fine pattern used in semiconductor devices such that improved durability against dry etching may be obtained and/or LER may be reduced. In addition, a fine pattern having a smaller feature size may be effectively realized by minimizing the deformation of sidewall profiles of apertures.

While example embodiments of the present invention have been particularly shown and described with reference to the drawings, it will be understood by those of ordinary skill in the art that various changes in form and details may be made therein without departing from the spirit and scope of the present invention as defined by the following claims.

1.-6. (canceled)

7. A method of forming a pattern,
comprising:
forming an underlayer on a semiconductor substrate;
forming a resist pattern having an aperture exposing the underlayer;
depositing a coating composition to the surface of the resist, the coating composition consisting essentially of a polymer including an aromatic ring having a vinyl ether functional group, and an organic solvent, wherein the concentration of the polymer is about 10 ppm to about 10 wt %, inclusive, based on a total weight of the organic solvent;
crosslinking the polymer to form an overcoating layer on the surface of the resist pattern; and
etching the underlayer using the resist pattern and the overcoating layer as an etch mask.

8. The method of claim 7, wherein the crosslinking of the polymer is induced by an acid catalyst.

9. The method of claim 7, wherein the polymer for overcoating is a Novolak resin partially substituted by a vinyl ether functional group.

10. The method of claim 7, wherein the polymer for overcoating is poly(hydroxystyrene) partially substituted by a vinyl ether functional group.

11. The method of claim 7, wherein the concentration of the polymer is about 10 ppm to about 10 wt %, inclusive, based on the total weight of the organic solvent.

12. The method of claim 7, wherein the organic solvent is alcohol.

13. The method of claim 7, wherein the coating composition further includes about 0.1 wt % to about 10 wt %, inclusive, of an acid based on the total weight of the coating composition.

14. The method of claim 8, wherein the acid catalyst is the acid in the resist pattern.

15. The method of claim 8, wherein the acid catalyst is one of trifluoroacetic acid, trifluoromethanesulfonic acid or a combination thereof.

16. The method of claim 7, wherein the resist pattern is a chemically amplified resist composition.

17. The method of claim 7, wherein the resist pattern is a resist composition for a KrF excimer laser having a wavelength of about 248 nm, a resist composition for an ArF excimer laser having a wavelength of about 193 nm or a resist composition an F₂ excimer laser having a wavelength of about 157 nm.

18. The method of claim 7, wherein the coating composition is deposited on the surface of the resist using spin coating, puddling, dipping or spraying.

19. The method of claim 7, wherein the crosslinking is induced at a temperature between about 90° C. and about 120° C., inclusive.

20. The method of claim 7, further including,
removing residual coating composition around the overcoating layer using an alkaline developing solution after forming of the overcoating layer.

21. The method of claim 20, wherein the developing solution is about 2.38 wt % of a tetramethylammonium hydroxide (TMAH) solution.
